(19) United States
(12) Patent Application Publication
(10) Pub. No.: US 2026/0183812 A1
(43) Pub. Date: Jul. 2, 2026

(54) APPARATUS FOR TRANSPORTING ARTICLES

(71) Applicant: Samsung Electronics Co., Ltd., Suwon-si (KR)

(72) Inventors: Young Wook KIM, Suwon-si (KR); Seung Gyu KANG, Suwon-si (KR); Kyu Sang KO, Suwon-si (KR); Jeong Jae BANG, Suwon-si (KR); So Young BAEK, Suwon-si (KR); Jae Sung BYUN, Suwon-si (KR); Hyun Woo LEE, Suwon-si (KR); Jun Hyuk CHANG, Suwon-si (KR)

(21) Appl. No.: 19/328,118

(22) Filed: Sep. 13, 2025

(30) Foreign Application Priority Data
Jan. 2, 2025 (KR) 10-2025-0000295

(51) Int. Cl. B08B 15/04; B65G 1/04

(52) U.S. Cl. CPC B08B 15/04; B65G 1/04; B65G 2201/0297; B65G 2207/26

(57) ABSTRACT

There is provided an article transporting apparatus capable of reducing outflow of foreign substances therefrom. The article transporting apparatus comprising a housing, a dust collecting device disposed inside the housing, a plurality of first wheel structures disposed inside the housing and configured to move the housing in a direction parallel to a first direction, a plurality of second wheel structures disposed inside the housing and configured to move the housing in a direction parallel to a second direction perpendicular to the first direction, a first wheel cover configured to surround at least a portion of each of the plurality of first wheel structures and to allow particles generated from each of the first wheel structures to flow into the housing and a second wheel cover configured to surround at least a portion of each of the plurality of second wheel structures and to allow particles generated from each of the second wheel structures to flow into the housing.

### CROSS-REFERENCE TO RELATED APPLICATION

This application claims priority under 35 U.S.C. § 119 from Korean Patent Application No. 10-2025-0000295, filed on Jan. 2, 2025, in the Korean Intellectual Property Office, and all the benefits accruing therefrom under 35 U.S.C. 119, the contents of which in its entirety are herein incorporated by reference.

### BACKGROUND

### Technical Field

The present disclosure relates to an article transporting apparatus.

### Description of Related Art

Semiconductor devices are manufactured in a clean room because high cleanliness is required for manufacturing thereof. Such a clean room is configured to maintain temperature, humidity, particles, etc. at predetermined levels to prevent product defects from occurring in a manufacturing step.

Thus, a worker inside the clean room not only wears clean clothes such as dustproof dress and dustproof shoes, but also undergoes an air shower process of removing dusts or foreign substances attached to the clean clothes before entering the clean room.

Further, a transport cart that transports materials or products while driving along a rail in the clean room performs movements including driving, vertical moment, transferring, and pivoting. Fine foreign substances may be generated during the movement.

A significant portion of these foreign substances are removed through the airflow in the clean room. However, a portion thereof accumulates on an upper surface of the driving rail, and are floated into the air due to turbulence generated when moving the transport cart and are introduced into the product manufacturing process.

Therefore, there is a need to develop a technology for solving this problem.

### SUMMARY

A purpose of the present disclosure is to provide an article transporting apparatus capable of reducing outflow of foreign substances therefrom.

The technical purposes of the present disclosure are not limited to the technical purposes as mentioned above, and other technical purposes not mentioned may be clearly understood by those skilled in the art from descriptions as set forth below.

According to an aspect of the present disclosure, there is provided an article transporting apparatus comprising a housing, a dust collecting device disposed inside the housing, a plurality of first wheel structures disposed inside the housing and configured to move the housing in a direction parallel to a first direction, a plurality of second wheel structures disposed inside the housing and configured to move the housing in a direction parallel to a second direction perpendicular to the first direction, a first wheel cover configured to surround at least a portion of each of the plurality of first wheel structures and to allow particles generated from each of the plurality of first wheel structures to flow into the housing and a second wheel cover configured to surround at least a portion of each of the plurality of second wheel structures and to allow particles generated from each of the plurality of second wheel structures to flow into the housing.

According to another aspect of the present disclosure, there is provided an article transporting apparatus comprising a driving rail including a plurality of first rails extending in a first direction and spaced apart from each other in a second direction perpendicular to the first direction and a plurality of second rails extending in the second direction and spaced apart from each other in the first direction and a transport robot configured to transport an article while moving in at least one of the first direction and the second direction and on the driving rail, wherein the transport robot includes a housing, a dust collecting device disposed inside the housing, a plurality of first wheel structures disposed inside the housing and configured to move the housing in a direction parallel to the first direction, a plurality of second wheel structures disposed inside the housing and configured to move the housing in a direction parallel to the second direction, a first wheel cover surrounding at least a portion of each of the plurality of first wheel structures and configured to allow particles generated from each of the plurality of first wheel structures to flow into the housing and a second wheel cover surrounding at least a portion of the plurality of second wheel structures and configured to allow particles generated from each of the plurality of second wheel structures to flow into the housing.

According to another aspect of the present disclosure, there is provided An article transporting apparatus comprising a driving rail including, a plurality of first rails extending in a first direction and spaced apart from each other in a second direction perpendicular to the first direction and a plurality of second rails extending in the second direction and spaced apart from each other in the first direction and a transport robot configured to transport an article while moving in at least one of the first direction and the second direction and on the driving rail, wherein the transport robot includes a housing, a dust collecting device disposed inside the housing, a plurality of first wheel structures disposed inside the housing and configured to move the housing in a direction parallel to the first direction, a plurality of second wheel structures disposed inside the housing and configured to move the housing in a direction parallel to the second direction, a first wheel cover surrounding at least a portion of each of the plurality of first wheel structures and configured to allow particles generated from each of the plurality of first wheel structures to flow into the housing and a second wheel cover surrounding at least a portion of the plurality of second wheel structures and configured to allow particles generated from each of the plurality of second wheel structures to flow into the housing, wherein the plurality of first wheel structures and the plurality of second wheel structures are driven by independent motors, respectively, wherein the housing includes a plurality of first housing plates disposed to face each other, a plurality of second housing plates connected to the plurality of first housing plates and disposed to face each other, a third housing plate covering tops of the first housing plates and the second housing plates and a plurality of housing plate supports connecting the plurality of first housing plates and the plurality of second housing plates to each other, wherein one of the plurality of second housing plates has an opening defined therein communicating with the dust collecting device.

Specific details of other embodiments are included in the detailed description and drawings.

### BRIEF DESCRIPTION OF DRAWINGS

The above and other aspects and features of the present disclosure will become more apparent by describing in detail embodiments thereof with reference to the attached drawings, in which:

FIG. 1 is a perspective view illustrating a transport robot according to some example embodiments of the present disclosure.

FIG. 2 is an exploded perspective view illustrating components of a transport robot according to some example embodiments of the present disclosure.

FIGS. 3 to 5 are perspective views showing a wheel structure and a wheel cover of a transport robot according to some example embodiments of the present disclosure.

FIG. 6 is a perspective view illustrating a dust collecting device of a transport robot according to some example embodiments of the present disclosure.

FIG. 7 is a plan view illustrating a driving rail and an article transporting apparatus according to some example embodiments of the present disclosure.

FIG. 8 is a perspective view illustrating a driving rail and an article transporting apparatus according to some example embodiments of the present disclosure.

FIG. 9 is a perspective view illustrating a transport robot disposed on a driving rail according to some example embodiments of the present disclosure.

FIGS. 10 and 11 are views illustrating an area A of FIG. 9 according to some example embodiments of the present disclosure.

FIG. 12 is a view illustrating the area A of FIG. 9 according to some example embodiments of the present disclosure.

### DETAILED DESCRIPTIONS

It will be understood that although the terms first, second, and the like are used herein to describe various elements, components, regions, layers and/or sections, these elements, components, regions, layers and/or sections are not limited by these terms. Unless the context indicates otherwise, these terms are merely used to distinguish one element, component, region, layer or section from another element, component, region, layer or section, for example as a naming convention. Thus, a first element, component, region, layer or section discussed below in one section of the specification could be termed a second element, component, region, layer or section in another section of the specification or in the claims without departing from the teachings of the present invention. In addition, in certain cases, even if a term is not described using “first,” “second,” etc., in the specification, it may still be referred to as “first” or “second” in a claim in order to distinguish different claimed elements from each other. Like reference characters refer to like elements throughout.

It will be understood that when an element is referred to as being “connected” or “coupled” to or “on” another element, it can be directly connected or coupled to or on the other element or intervening elements may be present. In contrast, when an element is referred to as being “directly connected” or “directly coupled” to another element, or as “contacting” or “in contact with” another element (or using any form of the word “contact”), there are no intervening elements present at the point of contact.

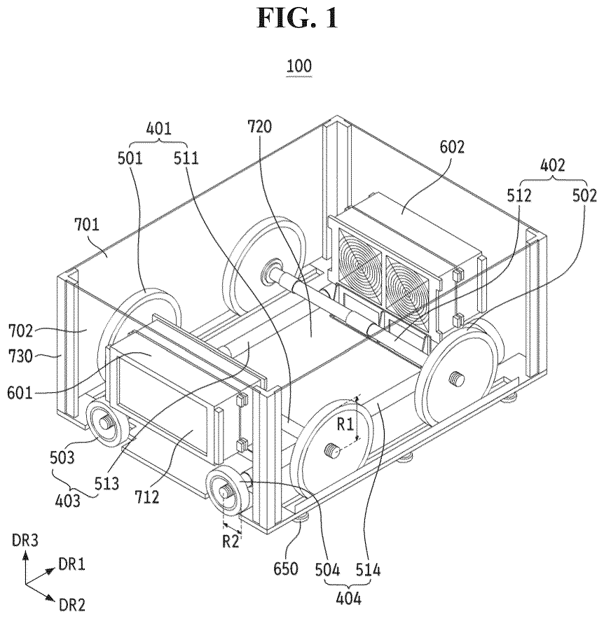

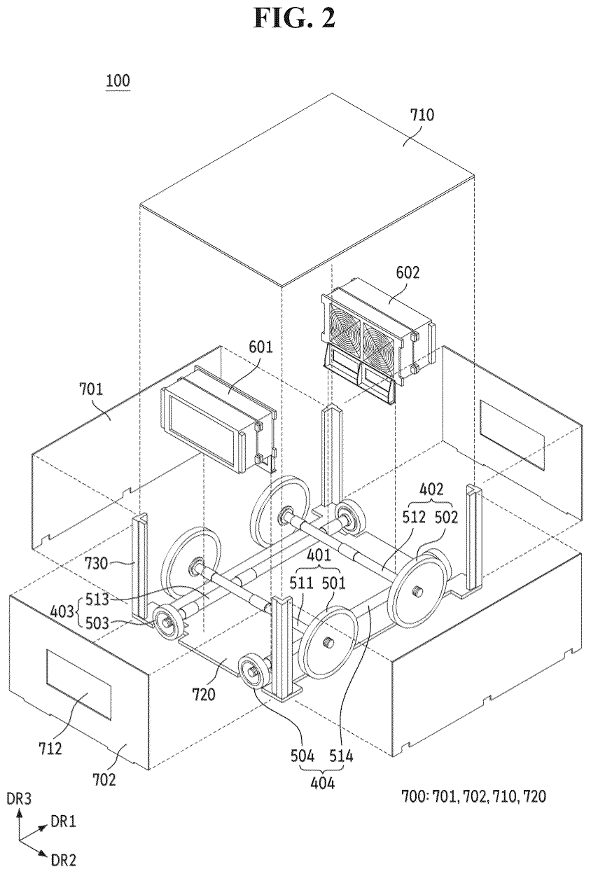

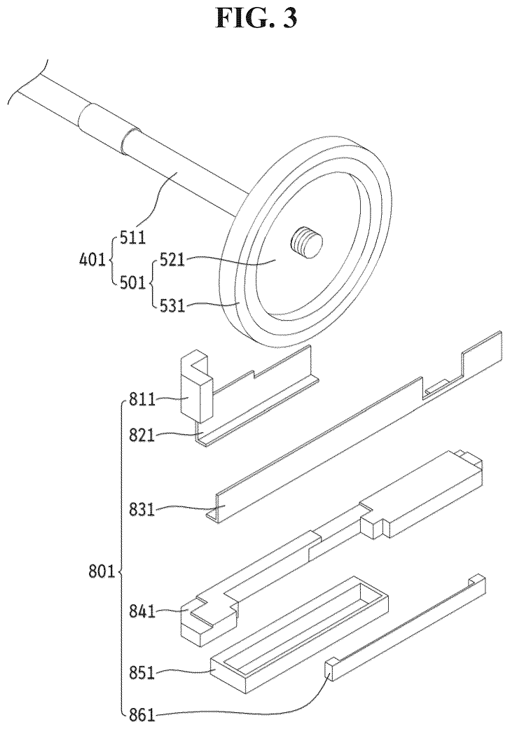

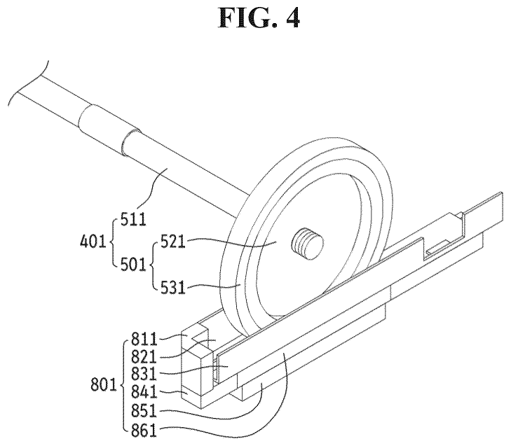

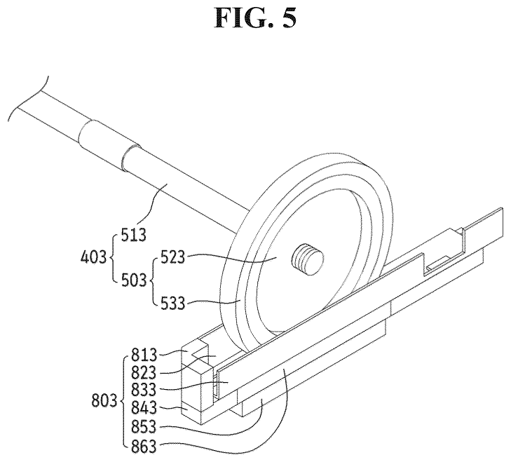

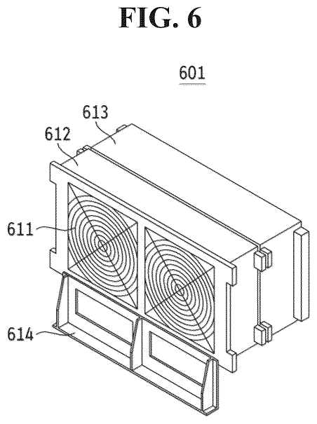

FIG. 1 is a perspective view illustrating a transport robot according to some example embodiments of the present disclosure. FIG. 2 is an exploded perspective view illustrating components of a transport robot according to some example embodiments of the present disclosure. FIGS. 3 to 5 are perspective views showing a wheel structure and a wheel cover of a transport robot according to some example embodiments of the present disclosure. FIG. 6 is a perspective view illustrating a dust collecting device of a transport robot according to some example embodiments of the present disclosure. For reference, in FIG. 1, an upper housing and the wheel cover are not illustrated for convenience of illustration, and in FIG. 2, a guide wheel and the wheel cover are not illustrated for convenience of illustration. For reference, FIG. 3 is a perspective view illustrating a state in which the wheel cover is disassembled, and FIGS. 4 and 5 are perspective views illustrating a state in which the wheel cover is assembled.

Referring to FIGS. 1 to 6, a transport robot 100 according to some example embodiments of the present disclosure may include a housing 700, a first wheel structure 401, a second wheel structure 402, a third wheel structure 403, a fourth wheel structure 404, a first dust collecting device 601, a second dust collecting device 602, a first wheel cover 801, and a plurality of guide wheels 650.

The housing 700 may include a plurality of first housing plates 701, a plurality of second housing plates 702, an upper housing plate 710, a lower housing plate 720, and a plurality of housing plate supports 730. An inner space of the transport robot 100 may be defined by the housing 700. In FIGS. 1 and 2, the housing 700 is illustrated as being made of a transparent material for convenience of illustration. However, an embodiment of the present disclosure is not limited thereto. In another example, the housing 700 may include an opaque material so that an inside of the transport robot 100 may not be visible to the outside.

The plurality of first housing plates 701 and the plurality of second housing plates 702 may be connected to each other. For example, the plurality of first housing plates 701 may include two first housing plates 701, and the plurality of second housing plates 702 may include two second housing plates 702. The pair of first housing plates 701 may be disposed to face each other. For example, the pair of first housing plates 701 may extend in parallel to one another. The pair of second housing plates 702 may be disposed to face each other. For example, the pair of second housing plates 702 may extend in parallel to one another. The first housing plate 701 and the second housing plate 702 may be arranged to be alternately repeated with each other. The pair of first housing plates 701 may be perpendicular to the pair of second housing plates 702. In a top plan view, an arrangement of the first housing plates 701 and the second housing plates 702 may have a rectangular shape.

The upper housing plate 710 may cover upper surfaces of the plurality of first housing plates 701 and the plurality of second housing plates 702. For example, edges of the upper housing plate 710 may overlap the upper surfaces of the plurality of first housing plates 701 and the plurality of second housing plates 702. The upper housing plate 710 may constitute an upper surface of the transport robot 100. The lower housing plate 720 may constitute a lower surface of the transport robot 100. The first housing plates 701 and the second housing plates 702 may be arranged around the upper housing plate 710. For example, the first housing plates 701 and the second housing plates 702 may extend along the inside of the edges of the upper housing plate 710. The first housing plates 701 and the second housing plates 702 may be arranged around the lower housing plate 720. For example, the first housing plates 701 and the second housing plates 702 may extend along the inside of the edges of the lower housing plate 720. The upper housing plate 710 and the lower housing plate 720 may be connected to each other via the first housing plates 701 and the second housing plates 702. For example, the first housing plates 701 and the second housing plates 702 may extend from a lower surface of the upper housing plate 710 to an upper surface of the lower housing plate 720. In example embodiments, the first housing plates 701 and the second housing plates 702 may contact the lower surface of the upper housing plate 710 and the upper surface of the lower housing plate 720.

The upper housing plate 710 and the lower housing plate 720 may have the same shape. For example, each of the upper housing plate 710 and the lower housing plate 720 may have a rectangular shape. In this case, a plurality of housing plate supports 730 may be respectively disposed at four vertices of each of the upper housing plate 710 and the lower housing plate 720. The plurality of housing plate supports 730 may extend in a third direction DR3. In this regard, the first direction DR1 and the second direction DR2 may be perpendicular to the third direction DR3. The first direction DR1 may intersect the second direction DR2.

The plurality of housing plate supports 730 may be disposed between the first housing plate 701 and the second housing plate 702. The plurality of housing plate supports 730 may be disposed between the upper housing plate 710 and the lower housing plate 720. For example, the plurality of housing plate supports 730 may extend from a lower surface of the upper housing plate 710 to an upper surface of the lower housing plate 720. In example embodiments, the plurality of housing plate supports 730 may contact the lower surface of the upper housing plate 710 and the upper surface of the lower housing plate 720. The plurality of housing plate supports 730 may connect the first housing plate 701 and the second housing plate 702 to each other. The plurality of housing plate supports 730 may connect the upper housing plate 710 and the lower housing plate 720 to each other. For example, when each of the upper housing plate 710 and the lower housing plate 720 have a rectangular shape, four housing plate supports 730 may be disposed. The plurality of housing plate supports 730 may serve to support the first housing plate 701 and the second housing plate 702 so as not to tilt in a different direction from the third direction DR3.

The first wheel structure 401 may include a plurality of first wheels 501 and a first wheel connection portion 511. For example, the first wheel structure 401 may include two first wheels 501 and one first wheel connection portion 511 connecting the two first wheels 501 to each other. The first wheel connection portion 511 may be disposed between two first wheels 501. The first wheel connection portion 511 may be disposed to connect the two first wheels 501 to each other. The first wheel connection portion 511 may connect the two first wheels 501 to each other such that the two first wheels 501 rotate in the same direction and at the same speed. The first wheels 501 may be respectively connected to both opposing ends of the first wheel connection portion 511. The first wheel connection portion 511 may extend in the second direction DR2. Both opposing ends of the first wheel connection portion 511 may be oriented to face the opposing first housing plates 701, respectively. In other words, both opposing ends of the first wheel connection portion 511 may be oriented to face the plurality of first housing plates 701 facing each other, respectively.

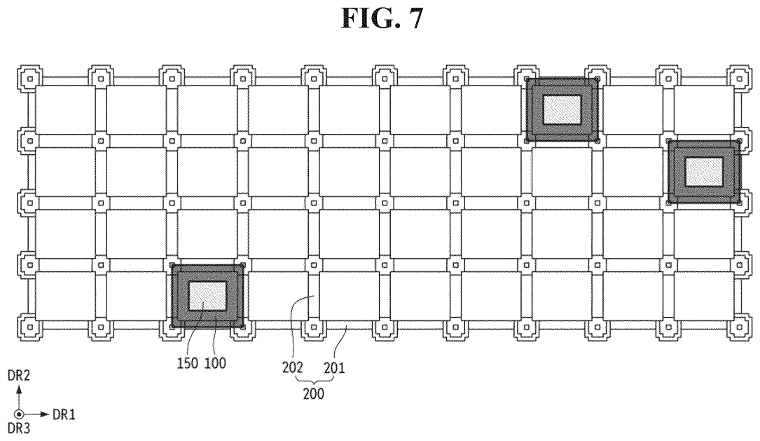

Since the description about each of the second wheel 502, the third wheel 503, and the fourth wheel 504 as described below is the same as the description of the first wheel 501, only the first wheel 501 will be representatively described below. The first wheel 501 may include a first wheel body portion 521 and a first wheel outer ring portion 531. The first wheel body portion 521 may be in direct contact with the first wheel connection portion 511. The first wheel body portion 521 may be directly connected to the first wheel connection portion 511. The first wheel outer ring portion 531 may be disposed to surround the first wheel body portion 521. The first wheel outer ring portion 531 may allow the transport robot 100 to move on a driving rail 200 (see FIG. 7). In other words, the first wheel outer ring portion 531 may be a portion of the transport robot 100 in direct contact with the driving rail 200. The first wheel body portion 521 and the first wheel outer ring portion 531 may include different materials. However, the present disclosure is not limited thereto. In another example, the first wheel body portion 521 and the first wheel outer ring portion 531 may include the same material.

The second wheel structure 402 may include a plurality of second wheels 502 and a second wheel connection portion 512. For example, the second wheel structure 402 may include two second wheels 502 and one second wheel connection portion 512 connecting the two second wheels 502 to each other. The second wheel connection portion 512 may be disposed between two second wheels 502. The second wheel connection portion 512 may be disposed to connect two second wheels 502 to each other. The second wheel connection portion 512 may connect the two second wheels 502 to each other such that the two second wheels 502 rotate in the same direction and at the same speed. The second wheels 502 may be respectively connected to both opposing ends of the second wheel connection portion 512. The second wheel connection portion 512 may extend in the second direction DR2. Each of both opposing ends of the second wheel connection portion 512 may be oriented to face each first housing plate 701. In other words, both opposing ends of the second wheel connection portion 512 may be oriented to face the plurality of first housing plates 701 facing each other, respectively. The first wheel connection portion 511 and the second wheel connection portion 512 may extend so as to be parallel to each other.

The third wheel structure 403 may include a plurality of third wheels 503 and a third wheel connection portion 513. For example, the third wheel structure 403 may include two third wheels 503 and one third wheel connection portion 513 connecting the two third wheels 503 to each other. The third wheel connection portion 513 may be disposed between two third wheels 503. The third wheel connection portion 513 may be disposed to connect two third wheels 503 to each other. The third wheel connection portion 513 may connect the two third wheels 503 to each other such that the two third wheels 503 rotate in the same direction and at the same speed. Each of the third wheels 503 may be connected to each of both opposing ends of the third wheel connection portion 513. The third wheel connection portion 513 may extend in the first direction DR1. Each of both opposing ends of the third wheel connection portion 513 may be oriented to face each second housing plate 702. In other words, both opposing ends of the third wheel connection portion 513 may be oriented to face the plurality of second housing plates 702 facing each other, respectively.

The fourth wheel structure 404 may include a plurality of fourth wheels 504 and a fourth wheel connection portion 514. For example, the fourth wheel structure 404 may include two fourth wheels 504 and one fourth wheel connection portion 514 connecting the two fourth wheels 504 to each other. The fourth wheel connection portion 514 may be disposed between two fourth wheels 504. The fourth wheel connection portion 514 may be disposed to connect two fourth wheels 504 to each other. The fourth wheel connection portion 514 may connect the two fourth wheels 504 to each other such that the two fourth wheels 504 rotate in the same direction and at the same speed. Each of the fourth wheels 504 may be connected to each of both opposing ends of the fourth wheel connection portion 514. The fourth wheel connection portion 514 may extend in the first direction DR1. Both opposing ends of the fourth wheel connection portion 514 may be oriented to face the second housing plates 702, respectively. In other words, both opposing ends of the fourth wheel connection portion 514 may be oriented to face the plurality of second housing plates 702 facing each other, respectively.

The first wheel structure 401 and the second wheel structure 402 may be driven by the same motor. In other words, the first wheel structure 401 and the second wheel structure 402 may be driven in the same direction and at the same speed. The motor driving the first wheel structure 401 and the second wheel structure 402 may be provided within the housing 700. The motor may be, for example, an AC induction motor or a servo motor.

The third wheel structure 403 and the fourth wheel structure 404 may be driven by the same motor. In other words, the third wheel structure 403 and the fourth wheel structure 404 may be driven in the same direction and at the same speed. The motor driving the third wheel structure 403 and the fourth wheel structure 404 may be provided within the housing 700. The motor may be, for example, an AC induction motor or a servo motor.

The first wheel structure 401 and the second wheel structure 402, and the third wheel structure 403 and the fourth wheel structure 404 may be driven by different motors, respectively. For example, while the first wheel structure 401 and the second wheel structure 402 are driven, the third wheel structure 403 and the fourth wheel structure 404 may not be driven. In another example, while the third wheel structure 403 and the fourth wheel structure 404 are driven, the first wheel structure 401 and the second wheel structure 402 may not be driven. In other words, the first wheel structure 401 and the second wheel structure 402, and the third wheel structure 403 and the fourth wheel structure 404 may be driven by independent motors, respectively.

The first wheel structure 401 and the second wheel structure 402 may have the same shape. In other words, the first wheel 501 and the second wheel 502 may have the same radius R1. The third wheel structure 403 and the fourth wheel structure 404 may have the same shape. In other words, the third wheel 503 and the fourth wheel 504 may have the same radius R2.

For convenience of description, hereinafter, the radii of the first wheel 501 and the third wheel 503 are representatively compared with each other. The radius R1 of the first wheel 501 may be greater than the radius R2 of the third wheel 503. In this case, the third wheel connection portion 513 may be disposed under the first wheel connection portion 511. In other words, in this case, the third wheel connection portion 513 may be disposed closer to the lower housing plate 720 than the first wheel connection portion 511 may be.

The first dust collecting device 601 and the second dust collecting device 602 may be disposed inside the transport robot 100. In other words, the first dust collecting device 601 and the second dust collecting device 602 may be disposed inside the housing 700. For example, each of the first dust collecting device 601 and the second dust collecting device 602 may extend in parallel with the second housing plate 702. Each of the first dust collecting device 601 and the second dust collecting device 602 may be connected to each of the second housing plates 702. For example, the first dust collecting device 601 may be connected to a first one of the second housing plates 702, and the second dust collecting device 602 may be connected to a second one of the second housing plates 702.

The first dust collecting device 601 and the second dust collecting device 602 may remove particles existing inside the housing 700. For example, the first dust collecting device 601 and the second dust collecting device 602 may remove particles generated from the first wheel structure 401, the second wheel structure 402, the third wheel structure 403, and the fourth wheel structure 404.

The first dust collecting device 601 and the second dust collecting device 602 may remove particles existing in the housing 700 to provide clean air into the clean room. For example, each of the first dust collecting device 601 and the second dust collecting device 602 may be embodied as a fan filter unit (FFU). However, an embodiment of the present disclosure is not limited thereto.

Hereinafter, for convenience of description, only the first dust collecting device 601 will be described. The second dust collecting device 602 may have the same configuration as that of the first dust collecting device 601. The first dust collecting device 601 may include a dust collecting device support 614, a fan 611, a fan cover 612, and a filter 613.

The dust collecting device support 614 may support the first dust collecting device 601 to be fixed in the transport robot. The dust collecting device support 614 may connect the first dust collecting device 601 and the lower housing plate 720 to each other. In other words, the dust collecting device support 614 may support the first dust collecting device 601 to be stably fixed to the lower housing plate 720.

Particles inside the transport robot 100 may be introduced into the first dust collecting device 601 under an operation of the fan 611. Particles introduced into the first dust collecting device 601 under an operation of the fan 611 may be introduced into the filter 613 through the fan cover 612. Particles may be filtered by the filter 613. The clean air from which the particles have been removed by the filter 613 may be discharged to the outside out of the transport robot 100. In other words, the clean air from which the particles have been removed may be introduced into the clean room.

An opening may be defined in a portion of the housing 700 connected to the first dust collecting device 601. For example, an opening 712 may be defined in the second housing plate 702 connected to the first dust collecting device 601. Each of the second housing plates 702 may have an opening 712 defined therein communicating with a respective one of the first dust collecting device 601 or the second dust collecting device 602. For example, a first one of the second housing plates 702 may have an opening 712 defined therein to communicate with the first dust collecting device 601, and a second one of the second housing plates 702 may have an opening 712 defined therein to communicate with the second dust collecting device 602. The clean air from which the particles have been removed may be introduced into the clean room through the opening 712. For example, air that has been cleaned by the first dust collecting device 601 may pass through the opening 712 to an exterior of the housing 700.

The first wheel cover 801 may be disposed to surround a portion of the first wheel 501. The first wheel cover 801 may include a first portion 811, a second portion 821, a third portion 831, a fourth portion 841, a fifth portion 851, and a sixth portion 861. However, an embodiment of the present disclosure is not limited thereto. In another example, the first wheel cover 801 may include four portions. The first wheel cover 801 may be disposed to surround a lower portion of the first wheel 501. The first wheel cover 801 may allow particles generated from the first wheel 501 to be introduced into the transport robot 100. For example, the first wheel cover 801 may allow particles generated from the first wheel 501 to flow into the housing 700 of the transport robot 100. The first wheel cover 801 may prevent the particles from being leaked to the outside out of the transport robot 100.

Although FIGS. 3 and 4 representatively illustrate only the first wheel cover 801 surrounding a portion of the first wheel 501, an embodiment of the present disclosure is not limited thereto. In an example embodiment, the first wheel cover 801 may surround a portion of the first wheel 501 and a portion of the second wheel 502. For example, a single first wheel cover 801 may extend along one of the first housing plates 701 below each of the first wheel 501 and the second wheel 502 and may surround portions of the first wheel 501 and the second wheel 502. In another example, it is obvious that a wheel cover surrounding a portion of the second wheel 502 may be disposed. The wheel cover surrounding a portion of the second wheel 502 may have the same shape and size as those of the first wheel cover 801.

A third wheel cover 803 may be disposed to surround a portion of the third wheel 503. The third wheel cover 803 may include a first portion 813, a second portion 823, a third portion 833, a fourth portion 843, a fifth portion 853, and a sixth portion 863. However, an embodiment of the present disclosure is not limited thereto. In another example, the third wheel cover 803 may include four portions. The third wheel cover 803 may be disposed to surround a lower portion of the third wheel 503. The third wheel cover 803 may allow the particles generated from the third wheel 503 to flow into the transport robot 100. For example, the third wheel cover 803 may allow particles generated from the third wheel 503 to flow into the housing 700 of the transport robot 100. The third wheel cover 803 may prevent the particles from being leaked to the outside out of the transport robot 100. In an example embodiment, the third wheel cover 803 may surround a portion of the third wheel 503 and a portion of the fourth wheel 504. For example, a single third wheel cover 803 may extend along one of the second housing plates 702 below each of the third wheel 503 and the fourth wheel 504 and may surround portions of the third wheel 503 and the fourth wheel 504.

Although FIG. 5 representatively shows only the third wheel cover 803 surrounding a portion of the third wheel 503, an embodiment of the present disclosure is not limited thereto. In another example, it is obvious that a wheel cover surrounding a portion of the fourth wheel 504 may be disposed. The wheel cover surrounding the portion of the fourth wheel 504 may have the same shape and size as those of the third wheel cover 803. Unlike the illustrated example, the third wheel cover 803 surrounding a portion of the third wheel 503 may have a different shape and size from those of the first wheel cover 801.

The plurality of guide wheels 650 may assist the transport robot 100 to balance when the transport robot 100 travels on the driving rail. In other words, the guide wheel 650 may assist the transport robot 100 to move with stability. FIG. 1 illustrates a case in which three guide wheels 650 are disposed under each of the first housing plates 701. However, an embodiment of the present disclosure is not limited thereto. In another example, two guide wheels 650 may be disposed under each first housing plate 701. In another example, three guide wheels 650 may be disposed under each second housing plate 702.

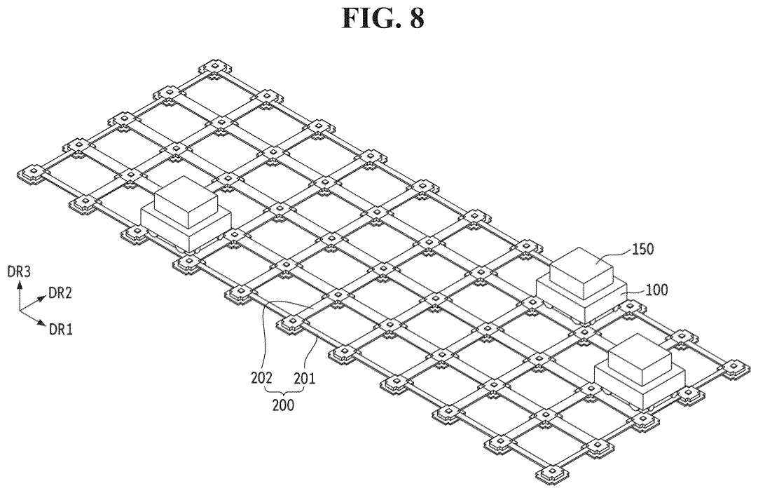

FIG. 7 is a plan view illustrating a driving rail and an article transporting apparatus according to some example embodiments of the present disclosure. FIG. 8 is a perspective view illustrating a driving rail and an article transporting apparatus according to some example embodiments of the present disclosure. For reference, in FIG. 7, the upper housing plate (e.g., upper housing plate 720 of FIG. 2) is not illustrated for convenience of illustration. For convenience of description, differences thereof from those as described in FIGS. 1 to 6 will be mainly described.

Referring to FIGS. 7 and 8, the article transporting apparatus according to some example embodiments of the present disclosure may include the driving rail 200, the transport robot 100, and a loading box 150. The transport robot 100 illustrated in FIG. 7 corresponds to the transport robot 100 of FIGS. 1 and 2.

The driving rail 200 may be configured to allow the transport robot 100 to travel thereon in the first direction DR1 and/or travel in the second direction DR2. The driving rail 200 may have a grid structure in a plan view.

The driving rail 200 may include a plurality of first rails 201 and a plurality of second rails 202. Each of the plurality of first rails 201 may extend in the first direction DR1 and may be spaced apart from each other in the second direction DR2. Each of the plurality of second rails 202 may extend in the second direction DR2 and may be spaced apart from each other in the first direction DR1. The traveling of the transport robot 100 in the first direction DR1 may be performed along the two first rails 201 adjacent to each other in the second direction DR2 among the plurality of first rails 201. For example, the transport robot 100 may travel in the first direction DR1 along the two first rails 201 parallel to each other in the second direction DR2. The traveling of the transport robot 100 in the second direction DR2 may be performed along two second rails 202 adjacent to each other in the first direction DR1 among the plurality of second rails 202. For example, the transport robot 100 may travel in the second direction DR2 along two second rails 202 parallel to each other in the first direction DR1.

A plurality of transport robots 100 may be disposed on the driving rail 200. Each of the plurality of transport robots 100 is configured to communicate with a higher system, and operations of the plurality of transport robots 100 may be controlled by the higher system. The higher system may be referred to as, for example, a controller. The higher system may include a memory device such as a read only memory (ROM), a random access memory (RAM), or the like, in which various programming instructions are stored, and a processor such as a microprocessor, a central processing unit (CPU), a graphics processing unit (GPU), or the like, configured to process the programming instructions stored in the memory device and signals provided from an external source. In addition, the higher system may include a receiver and a transmitter for receiving and transmitting an electrical signal to and from each of the plurality of transport robots 100. For example, the higher system (or controller) may include a memory device in which is stored instructions that, when executed by the processor, cause the processor to transmit and/or receive data and/or instructions to and/or from the plurality of transport robots 100. The instructions may include, for example, speed and direction of movement or travel of each of the plurality of transport robots 100, speed or direction of rotation of each of the first to fourth wheels 501 to 504, activation and deactivation of the first and second dust collecting devices 601 and 602, etc.

The loading box 150 may be disposed on the transport robot 100. The transport robot 100 may be configured to transport an article via the loading box 150. In some embodiments, the transport robot 100 may be provided in a semiconductor device manufacturing plant and may be configured to transport the loading box 150 within the semiconductor device manufacturing plant. For example, the loading box 150 may be a container in which a substrate used for manufacturing a semiconductor device is received. For example, the loading box 150 may include any one of a hermetic container such as a front open unified pod (FOUP) configured to receive a plurality of substrates therein, a magazine configured to receive a plurality of substrates therein, and a tray configured to receive a plurality of substrates therein. In some embodiments, the loading box 150 may be the substrate itself.

The transport robot 100 may hold the loading box 150 and may be responsible for transporting the loading box 150 in the first direction DR1 and the second direction DR2. The transport robot 100 may transport the loading box 150 by moving the loading box 150 in a state of holding the loading box 150 from a designated start position of the driving rail 200 to a designated target position thereof. The transport robot 100 may alternately move on and along the first rails 201 and the second rails 202. For example, the transport robot 100 may move in the first direction DR1 along the first rail 201, move in the second direction DR2 along the second rail 202, and then move again in the first direction DR1 along the first rail 201. In another example, the mobile transport robot 100 may move in the second direction DR2 along the second rail 202 and then move in the first direction DR1 along the first rail 201.

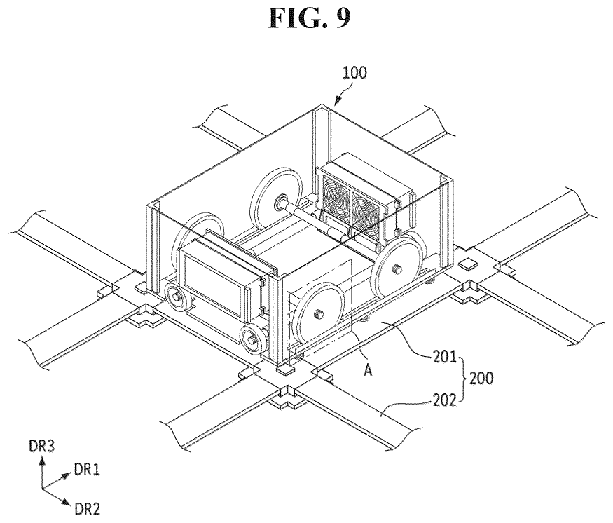

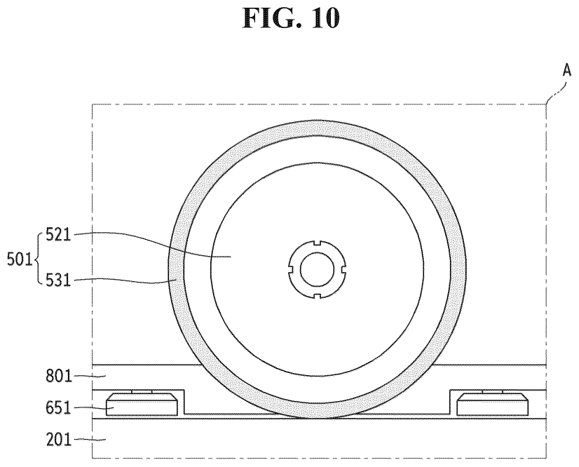

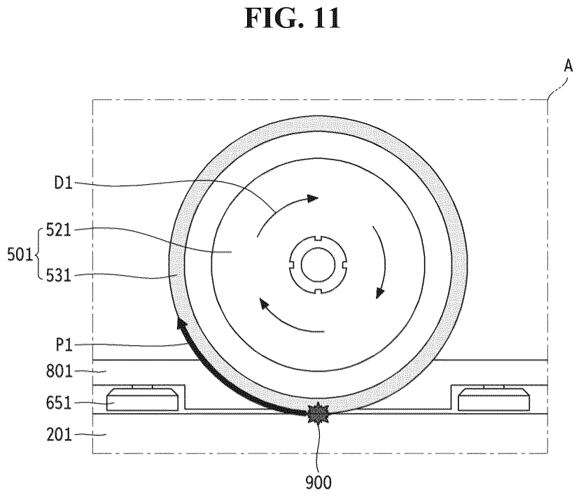

FIG. 9 is a perspective view illustrating a transport robot disposed on a driving rail according to some example embodiments of the present disclosure. FIGS. 10 and 11 are views illustrating an area A of FIG. 9 according to some example embodiments of the present disclosure. For reference, FIG. 10 is a view showing a transport robot in a stopped state, and FIG. 11 is a view showing a transport robot when the first wheel structure 401 rotates clockwise.

Referring to FIGS. 9 to 11, the transport robot 100 according to some example embodiments of the present disclosure may move on the driving rail 200.

The first wheel outer ring portion 531 may be in direct contact with the driving rail 200. Specifically, the first wheel outer ring portion 531 may be in direct contact with the first rail 201. When the transport robot 100 moves in the first direction DR1, the first wheel outer ring portion 531 and the first rail 201 may come into contact with each other.

Particles 900 may be generated due to the contact between the first wheel outer ring portion 531 and the first rail 201. The particles 900 may be introduced into the transport robot 100 by the first wheel cover 801. The first wheel cover 801 may prevent the particles 900 from being leaked to the outside out of the transport robot 100. For example, when the first wheel 501 rotates in the clockwise direction D1, the particles 900 generated from the contact between the first wheel outer ring portion 531 and the first rail 201 may be introduced into the transport robot 100 along a first path P1. The particles 900 introduced into the transport robot 100 along the first path P1 may be filtered by at least one of the first dust collecting device 601 and the second dust collecting device 602. The clean air from which the particles 900 have been removed may be discharged to the outside out of the transport robot 100.

FIGS. 10 and 11 illustrate only the particles 900 generated from the contact between the first wheel 501 and the first rail 201. However, this is only for convenience of description. Particles generated from the contact between the second wheel 502 and the first rail 201, the contact between the third wheel 503 and the second rail 202, and the contact between the fourth wheel 504 and the second rail 202 may also be filtered by at least one of the first dust collecting device 601 and the second dust collecting device 602.

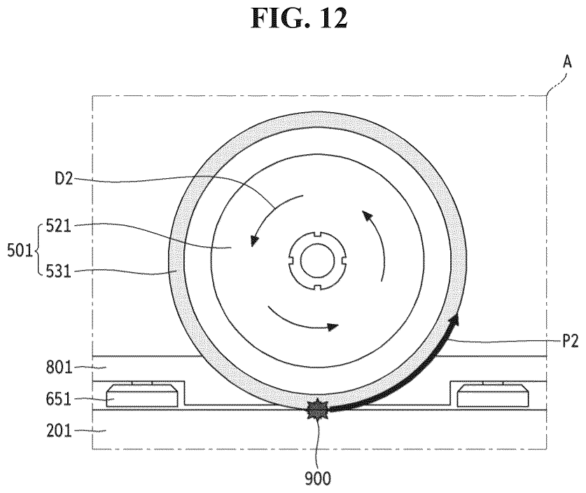

FIG. 12 is a view illustrating the area A of FIG. 9 according to some example embodiments of the present disclosure. For reference, FIG. 12 is a view illustrating a transport robot when the first wheel structure 401 rotates counterclockwise. For convenience of description, in FIG. 12, differences thereof from those as described in FIGS. 9 to 11 will be mainly described.

When the first wheel 501 rotates in the counterclockwise direction D2, the particles 900 generated from contact between the first wheel outer ring portion 531 and the first rail 201 may be introduced into the transport robot 100 along a second path P2. The particles 900 introduced into the transport robot 100 along the second path P2 may be filtered by at least one of the first dust collecting device 601 and the second dust collecting device 602. The clean air from which the particles 900 have been removed may be discharged to the outside out of the transport robot 100.

FIG. 12 shows only the particles 900 generated from the contact between the first wheel 501 and the first rail 201. However, this is only for convenience of description. Particles generated from the contact between the second wheel 502 and the first rail 201, the contact between the third wheel 503 and the second rail 202, and the contact between the fourth wheel 504 and the second rail 202 may also be filtered by at least one of the first dust collecting device 601 and the second dust collecting device 602.

Although embodiments of the present disclosure have been described above with reference to the accompanying drawings, the present disclosure may not be limited to embodiments and may be implemented in various different forms. Those of ordinary skill in the technical field to which the present disclosure belongs will be able to appreciate that the present disclosure may be implemented in other specific forms without changing the technical idea or essential features of the present disclosure. Therefore, it should be understood that embodiments as described above are not restrictive but illustrative in all respects.

What is claimed is:

1. An article transporting apparatus comprising:
a housing;
a dust collecting device disposed inside the housing;
a plurality of first wheel structures disposed inside the housing and configured to move the housing in a direction parallel to a first direction;
a plurality of second wheel structures disposed inside the housing and configured to move the housing in a direction parallel to a second direction perpendicular to the first direction;
a first wheel cover configured to surround at least a portion of each of the plurality of first wheel structures and to allow particles generated from each of the first wheel structures to flow into the housing; and
a second wheel cover configured to surround at least a portion of each of the plurality of second wheel structures and to allow particles generated from each of the second wheel structures to flow into the housing.

2. The article transporting apparatus of claim 1, wherein the plurality of first wheel structures and the plurality of second wheel structures are driven by independent motors, respectively.

3. The article transporting apparatus of claim 1,
wherein the housing includes:
a plurality of first housing plates disposed to face each other;
a plurality of second housing plates connected to the plurality of first housing plates and disposed to face each other; and
a third housing plate covering tops of the first housing plates and the second housing plates, and
wherein one of the second housing plates has an opening defined therein communicating with the dust collecting device.

4. The article transporting apparatus of claim 3,
wherein each of the plurality of first wheel structures includes a plurality of first wheels and a first wheel connection portion connecting the plurality of first wheels to each other,
wherein each of the plurality of second wheel structures includes a plurality of second wheels and a second wheel connection portion connecting the plurality of second wheels to each other,
wherein the first wheel connection portion of each of the plurality of first wheel structures extends in parallel with the second direction,
wherein the second wheel connection portion of each of the plurality of second wheel structures extends in parallel with the first direction,
wherein the dust collecting device extends in parallel with the one of the plurality of second housing plates, and
wherein a radius of each of the plurality of first wheels is greater than a radius of each of the plurality of second wheels.

5. The article transporting apparatus of claim 4,
wherein each of the plurality of first wheels includes a first wheel body portion and a first outer ring portion disposed to surround an outer periphery of the first wheel body portion, and
wherein each of the plurality of second wheels includes a second wheel body portion and a second outer ring portion disposed to surround an outer periphery of the second wheel body portion.

6. The article transporting apparatus of claim 3, wherein the housing further includes a plurality of housing plate supports connecting the plurality of first housing plates and the plurality of second housing plates to each other.

7. The article transporting apparatus of claim 1, further comprising:
a loading box disposed on the housing and configured to load an article therein,
wherein the article received in the loading box is transported between a plurality of equipment.

8. The article transporting apparatus of claim 7, wherein the loading box is configured to receive a substrate therein.

9. The article transporting apparatus of claim 1, further comprising:
a driving rail disposed under the housing,
wherein the driving rail is in direct contact with one of the plurality of first wheel structures and the plurality of second wheel structures.

10. An article transporting apparatus comprising:
a driving rail including:
a plurality of first rails extending in a first direction and spaced apart from each other in a second direction perpendicular to the first direction; and
a plurality of second rails extending in the second direction and spaced apart from each other in the first direction; and
a transport robot configured to transport an article while moving in at least one of the first direction and the second direction and on the driving rail,
wherein the transport robot includes:
a housing;
a dust collecting device disposed inside the housing;
a plurality of first wheel structures disposed inside the housing and configured to move the housing in a direction parallel to the first direction;
a plurality of second wheel structures disposed inside the housing and configured to move the housing in a direction parallel to the second direction;
a first wheel cover surrounding at least a portion of each of the plurality of first wheel structures and configured to allow particles generated from each of the plurality of first wheel structures to flow into the housing; and
a second wheel cover surrounding at least a portion of the plurality of second wheel structures and configured to allow particles generated from each of the plurality of second wheel structures to flow into the housing.

11. The article transporting apparatus of claim 10, wherein at least one of the plurality of first wheel structures and at least one of the plurality of second wheel structures is in direct contact with the driving rail.

12. The article transporting apparatus of claim 10, further comprising:
a loading box disposed on the transport robot and configured to load an article therein,
wherein the article received in the loading box is transported between a plurality of equipment.

13. The article transporting apparatus of claim 12, wherein the loading box is configured to receive a substrate therein.

14. The article transporting apparatus of claim 10,
wherein the housing includes:
a plurality of first housing plates disposed to face each other;
a plurality of second housing plates connected to the plurality of first housing plates and disposed to face each other; and
a third housing plate covering tops of the first housing plates and the second housing plates, and
wherein one of the second housing plates has an opening defined therein communicating with the dust collecting device.

15. The article transporting apparatus of claim 14,
wherein each of the plurality of first wheel structures includes a plurality of first wheels and a first wheel connection portion connecting the plurality of first wheels to each other,
wherein each of the plurality of second wheel structures includes a plurality of second wheels and a second wheel connection portion connecting the plurality of second wheels to each other,
wherein the first wheel connection portion of each of the plurality of first wheel structures extends in parallel with the second direction,
wherein the second wheel connection portion of each of the plurality of second wheel structures extends in parallel with the first direction,
wherein the dust collecting device extends in parallel with the one of the plurality of second housing plates, and
wherein a radius of each of the plurality of first wheels is greater than a radius of each of the plurality of second wheels.

16. The article transporting apparatus of claim 15,
wherein each of the plurality of first wheels includes a first wheel body portion and a first outer ring portion disposed to surround an outer periphery of the first wheel body portion, and
wherein each of the plurality of second wheels includes a second wheel body portion and a second outer ring portion disposed to surround an outer periphery of the second wheel body portion.

17. The article transporting apparatus of claim 16,
wherein the first outer ring portion is in direct contact with a first rail of the first rails and moves the housing, and
wherein the second outer ring portion is in direct contact with a second rail of the second rails and moves the housing.

18. The article transporting apparatus of claim 14, wherein the housing further includes a plurality of housing plate supports connecting the plurality of first housing plates and the plurality of second housing plates to each other.

19. An article transporting apparatus comprising:
a driving rail including:
a plurality of first rails extending in a first direction and spaced apart from each other in a second direction perpendicular to the first direction; and
a plurality of second rails extending in the second direction and spaced apart from each other in the first direction; and
a transport robot configured to transport an article while moving in at least one of the first direction and the second direction and on the driving rail,
wherein the transport robot includes:
a housing;
a dust collecting device disposed inside the housing;
a plurality of first wheel structures disposed inside the housing and configured to move the housing in a direction parallel to the first direction;
a plurality of second wheel structures disposed inside the housing and configured to move the housing in a direction parallel to the second direction;
a first wheel cover surrounding at least a portion of each of the plurality of first wheel structures and configured to allow particles generated from each of the plurality of first wheel structures to flow into the housing; and
a second wheel cover surrounding at least a portion of the plurality of second wheel structures and configured to allow particles generated from each of the plurality of second wheel structures to flow into the housing,
wherein the plurality of first wheel structures and the plurality of second wheel structures are driven by independent motors, respectively,
wherein the housing includes:
a plurality of first housing plates disposed to face each other;
a plurality of second housing plates connected to the plurality of first housing plates and disposed to face each other;
a third housing plate covering tops of the first housing plates and the second housing plates; and
a plurality of housing plate supports connecting the plurality of first housing plates and the plurality of second housing plates to each other, and
wherein one of the plurality of second housing plates has an opening defined therein communicating with the dust collecting device.

20. The article transporting apparatus of claim 19,
wherein each of the plurality of first wheel structures includes a plurality of first wheels and a first wheel connection portion connecting the plurality of first wheels to each other,
wherein each of the plurality of second wheel structures includes a plurality of second wheels and a second wheel connection portion connecting the plurality of second wheels to each other,
wherein the first wheel connection portion of each of the plurality of first wheel structures extends in parallel with the second direction,
wherein the second wheel connection portion of each of the plurality of second wheel structures extends in parallel with the first direction,
wherein the dust collecting device extends in parallel with the one of the plurality of second housing plates, and
wherein a radius of each of the plurality of first wheels is greater than a radius of each of the plurality of second wheels.
